(19) United States
(12) Patent Application Publication
(10) Pub. No.: US 2007/0121773 A1
(43) Pub. Date: May 31, 2007

(54) PHASE LOCKED LOOP CIRCUIT

(76) Inventors: Chi-Kung Kuan, Ta-Hsi Town (TW); Yu-Pin Chou, Tung-Hsiao Town (TW)

Correspondence Address: NORTH AMERICA INTELLECTUAL PROPERTY CORPORATION, P.O. BOX 506, MERRIFIELD, VA, 22116, US

(21) Appl. No.: 11/561,904

(22) Filed: Nov. 21, 2006

(30) Foreign Application Priority Data
Nov. 25, 2005 (TW) 094141473

(51) Int. Cl. H03D 3/24

(52) U.S. Cl. 375/376

(57) ABSTRACT

A phase locked loop circuit includes a phase locked loop for generating a plurality of first output signals each having a different phase but a same frequency according to a first reference signal; a control loop for generating a phase selection signal according to a second reference signal and a second output signal outputted by the phase locked loop, wherein a frequency of the second output signal is substantially equal to the frequency of the first output signals; and a phase selector for receiving the first output signals and the phase selector signal, and according to the phase selector signal selecting one of the first output signals to be a first feedback signal; wherein the first feedback signal is inputted to the phase locked loop.

### BACKGROUND OF THE INVENTION

1. Field of the Invention

The invention relates to a phase locked loop circuit, and more particularly, to a phase locked loop circuit used in a displaying device.

2. Description of the Prior Art

The output video signal from a video card in a computer is usually an analog signal. When the analog signal is inputted into a display device such as a liquid crystal display (LCD), an analog to digital converter within the display device is utilized to convert the analog signal into a digital signal for display on the display device. When outputting the analog signal, the video card will typically include synchronization signal such as a horizontal H-Sync (15 KHz-150 KHz) and a vertical V-Sync (60 Hz-75Hz) to the analog to digital converter. Because the frequencies of the synchronization signals H-Sync, V-Sync are very low, they are unable to be used by the analog to digital converter as sampling clocks. For this reason, a phase locked loop must be included to provide a suitable reference signal to the analog to digital converter according to the synchronization signals.

Traditional phase locked loop design and usage is well known by those of ordinary skill in the art. More information about related art phase lock loop technology can be found in U.S. Pat. No. 6,686,784 and U.S. Pat. No. 6,404,247.

### SUMMARY OF THE INVENTION

One objective of the claimed invention is therefore to provide a phase locked loop, to solve the above-mentioned problem.

According to an exemplary embodiment of the claimed invention, a phase locked loop circuit is disclosed comprising a phase locked loop for generating a plurality of first output signals each having a different phase but a same frequency according to a first reference signal; a control loop for generating a phase selection signal according to a second reference signal and a second output signal outputted by the phase locked loop, wherein a frequency of the second output signal is substantially equal to the frequency of the first output signals; and a phase selector for receiving the first output signals and the phase selector signal, and according to the phase selector signal selecting one of the first output signals to be a first feedback signal; wherein the first feedback signal is inputted to the phase locked loop.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a block diagram of the structure of a phase locked loop circuit according to an exemplary embodiment of the present invention.

FIG. 2 shows a waveform diagram of signals in the phase locked loop circuit of FIG. 1.

### DETAILED DESCRIPTION

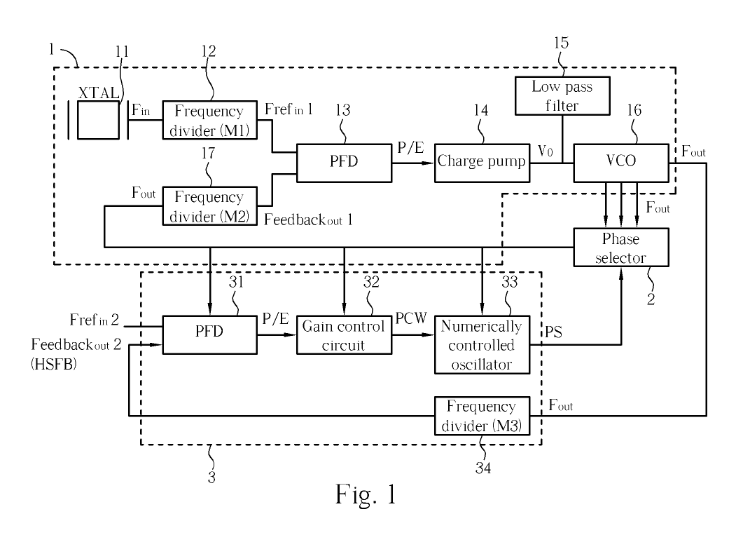

FIG. 1 shows a block diagram of the structure of a phase locked loop circuit according to an exemplary embodiment of the present invention. As shown in FIG. 1, the structure includes a phase locked loop 1, a phase selector 2, and a control loop 3. In this embodiment, the phased lock loop 1 includes a first frequency divider 12, a first phase frequency detector (PFD) 13, a charge pump 14, a low pass filter 15, a voltage controlled oscillator (VCO) 16, and a second frequency divider 17. In this embodiment, the phase locked loop 1 is an analog phase locked loop. Furthermore, the control loop 3 further includes a second phase frequency detector (PFD) 31, a gain control circuit 32, a numerically controlled oscillator 33, and a third frequency divider 34. The above listed elements of this embodiment operate according to the well known operating principles already understood by a person of ordinary skill in the art and further description is omitted herein for brevity. Additionally, the gain control circuit 32 can be implemented in this embodiment as a proportional-integral controller (PI controller); however, the present invention is not limited to such implementation. Also, in other embodiments, the VCO 16 could also be replaced with a capacitance or a current controlled oscillator. Finally, in this embodiment, the numerically controlled oscillator 33 is implemented as a sigma-delta modulator (SDM).

The above described phase locked loop 1 utilizes a crystal oscillator 11 to produce a reference input signal (Fᵢₙ). The above described first frequency divider 12, the second frequency divider 17, and the third frequency divider 13 can each be implemented by a typical divider device, and these divider devices 12, 17, 34 are each for inputting an analog signal and respectively performing integer dividing operations according to factors of M₁, M₂, and M₃ to thereby generate output signals. The factors M₁, M₂, and M₃ can be integers from 1-1000.

In the phase locked loop 1, the first PFD 13 detects a difference between a first reference input signal Frefᵢₙ1 and a first feedback output signal Feedbackₒᵤₜ1 to thereby generate a first phase error P/E signal. The charge pump 14 receives the first P/E signal outputted by the first PFD 13 and generates a corresponding output control voltage. After passing through the low pass filter 15 to remove low frequency components, the filtered signal is then passed to the VCO 16. The VCO 16 is for generating a corresponding first output signal F_{OUT} according to a size of the output control voltage. In this embodiment, the outputted first output signal F_{OUT} outputted by the VCO 16 includes several differently phased signals each having the same frequency, and these signals are passed to the phase selector 2 and the third frequency divider 34.

As stated above, after passing the first output signal F_{OUT} to the third frequency divider 34, it becomes the second feedback output signal Feedbackₒᵤₜ2 inputted to the second PFD 31. The second feedback output signal Feedbackₒᵤₜ2 can be utilized as the horizontal synchronization control signal (HSFB) required by the analog/digital converter in the LCD display.

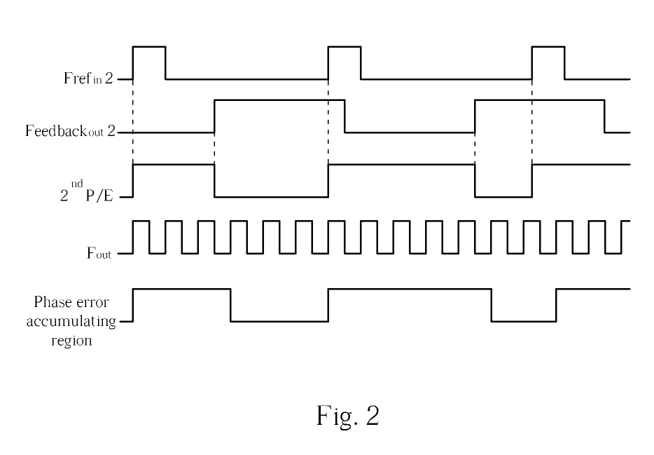

Referring to FIG. 2, in the above described control loop 3, the second PFD 31 is utilized for detecting a difference between the second input signal Frefᵢₙ2 and a second feedback output signal Feedbackₒᵤₜ2 to thereby generate a second phase error P/E signal. The second P/E signal is a numerical signal and indicates a number of pulses included in the output signal F_{OUT} in the phase error region of the second reference input signal Frefᵢₙ2 and the second feedback output signal Feedbackₒᵤₜ2. In this embodiment, the second reference input signal Frefᵢₙ2 is the horizontal synchronization control signal (HSFB) for the LCD control chip. The gain control device 32 receives the second P/E signal outputted by the second PFD 31 and generates a digital control signal (PCW). As shown in FIG. 2, when the duty cycle of the second P/E signal increases, this means the phase error between the second reference input signal Frefᵢₙ2 and the second feedback output signal Feedbackₒᵤₜ2 is also increasing.

The above described gain control device 32 can be implemented utilizing a proportional-integral controller (PI controller), which is formed using a numerical pump and a digital filter. In the gain control device 32, the numerical pump receives the second P/E signal to thereby generate a ratio output signal and an integral output signal. Next, the ratio signal and the integral output signal are inputted to the digital filter, which thereafter produces the digital control signal (PCW).

After the above described numerically controlled oscillator 33 receives the digital control signal PCW outputted by the gain control device 32, it uses a numerical control format to generate a phase selection PS signal for transfer to the phase selector 2.

In this embodiment, the above described numerically controlled oscillator 32 can be implemented utilizing an accumulator circuit. The numerically controlled oscillator 33 utilizes the output signal F_{OUT} as the independent clock, and continually accumulates the digital control signal PCW so as to generate a phase adjustment value. A positive or negative sign of the phase adjustment signal represents selecting either a leading or lagging phase. Furthermore, as the phase adjustment value increases, this represents selecting an increased leading phase; oppositely, as the phase adjustment value decreases, this represents selecting an increased lagging phase. Because of such operation, the numerically controlled oscillator 33 generates the phase selection PS signal according to the phase adjustment signal, and passes the PS signal to the phase selector 2. Therefore, as the digital control signal PCW increases in value, this represents the phase selector 2 must select a leading phase signal have an increased phase lead value. The opposite situation represents that the phase selector 2 must select a lagging phase signal have an increased phase lag value. The above mentioned accumulator device can be implemented using an accumulator or a progressively increasing and decreasing counter combination.

Referring again to FIG. 1, the phase selector 2 receives the first output signal F_{OUT} outputted by the voltage controlled oscillator VCO 16. The first output signal F_{OUT} includes a plurality of signals having different phases but the same frequency. The phase selector 2 selects either a leading or lagging adjusted phase value according to the phase selecting P/S signal outputted by the numerically controlled oscillator 33. That is, the phase selector 2 selects for output one of the plurality of signals having different phases but the same frequency. In this embodiment, in order to ensure the phase locked loop achieves a locked condition and achieve the goal of generating the first output signal, it can be implemented by suitable adjustment utilizing the factors M₁ and M₂ of the frequency dividers 12 and 17.

Continuing the above description, when the frequency and phase of the second feedback output signal Feedbackₒᵤₜ2 are not equal to the frequency and phase of the second reference input signal Frefᵢₙ2, the control loop 3 will output a phase selecting PS signal and select the phase of the first output signal F_{OUT}. When the first feedback output signal Feedbackₒᵤₜ1 generated by the first output signal F_{OUT} divided by the factor M₂ does not have a frequency and phase being equal to the frequency and phase of the first reference input signal Frefᵢₙ1, the phase locked loop 1 will correspondingly adjust the frequency of the first outputted signal F_{OUT}. In this way, the phase locked loop 1 will be able to generate the first output signal F_{OUT} according to the second reference input voltage Frefᵢₙ2. The phase locked loop 1 is able to according to the horizontal synchronization control signal (HSFB) generate the sampling reference clock required by the analog and digital converter device.

As can be understood from the above description, in this embodiment, because the frequency of the first output signal F_{OUT} is greater than the second reference input signal Frefᵢₙ2, the bandwidth of the analog phase lock loop 1 is widened while jitter produced by the voltage controlled oscillator 16 is suppressed. This thereby reduces the jitter of the output signal F_{OUT}. Also, because the phase locked loop 1 receives the first reference input signal Frefᵢₙ1 having both increased frequency and increased signal quality, and does not receive the second reference input signal Frefᵢₙ2 having the decreased frequency, the bandwidth design of the phase locked loop 1 can avoid the limits of the second reference input signal Frefᵢₙ2. Therefore, is able to achieve the goal of utilizing the phase locked loop 1 to provide a stable oscillation signal. After F_{OUT} is divided at the second frequency divider 17 to produce the first feedback output signal Feedbackₒᵤₜ1 the frequency of Feedbackₒᵤₜ1 should be the same as that of the first reference input signal Frefᵢₙ1. In this way, a stable oscillation of the phase locked loop is achieved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A phase locked loop circuit comprising:
a phase locked loop for generating a plurality of first output signals each having a different phase but a same frequency according to a first reference signal;
a control loop for generating a phase selection signal according to a second reference signal and a second output signal outputted by the phase locked loop, wherein a frequency of the second output signal is substantially equal to the frequency of the first output signals; and
a phase selector receiving the first output signals and the phase selector signal for selecting one of the first output signals to be a first feedback signal according to the phase selector signal;
wherein the first feedback signal is inputted to the phase locked loop.

2. The phase locked loop circuit of claim 1, wherein the phase locked loop comprising:
a first frequency divider for receiving the first reference signal and dividing the first reference signal to thereby generate a third reference signal;
a first phase frequency detector for generating a first phase error signal according to the third reference signal;
a charge pump for receiving the first phase error signal and generating an output control voltage;
an oscillator for generating the first output signal according to the output control voltage; and
a second frequency divider for dividing a frequency of the first output signal outputted by the phase selector to thereby generate the first feedback signal, and for passing the first feedback signal to the first phase frequency detector.

3. The phase locked loop circuit of claim 2, wherein the oscillator is a voltage or current controlled oscillator.

4. The phase locked loop circuit of claim 1, wherein the control loop comprising:
a second phase frequency detector for generating a second phase error signal according to the second reference signal and a second feedback output signal;
a gain control device for generating a digital control signal according to the second phase error signal;
a numerically controlled voltage oscillator for generating the phase selector signal according to the digital control signal; and
a third frequency divider for dividing the second output signal to thereby generate the second feedback output signal.

5. The phase locked loop circuit of claim 4, wherein the gain control device is a proportional-integral controller.

6. The phase locked loop circuit of claim 5, wherein the gain control device comprises:
a numerical pump for generating a ratio output signal and an accumulated output signal according to the second phase error signal; and
a digital filter for generating the digital control signal according to the ratio output signal and the accumulated output signal.

7. The phase locked loop circuit of claim 4, wherein the numerically controlled oscillator is a sigma-delta modulator.

8. The phase locked loop circuit of claim 7, wherein the sigma-delta modulator is for accumulating the digital control signal to thereby generate the phase selection signal.

9. The phase locked loop circuit of claim 1, wherein the phase locked loop is an analog phase locked loop.

10. The phase locked loop circuit of claim 1, wherein a frequency of the first reference signal is greater than a frequency of the second reference signal.

11. The phase locked loop circuit of claim 1, wherein the second reference signal is a horizontal synchronization control signal (HSFB).

12. A phase locked loop circuit comprising:
a first loop for generating a plurality of first output signals each having different phase but same frequency according to a first reference signal;
a second loop for generating a phase selection signal according to a second reference signal and one of the first output signals; and
a phase selector receiving the first output signals for selecting one of the first output signals to be a first feedback signal according to the phase selector signal;
wherein the first feedback signal is inputted to the first loop; and the frequency of first reference signal is greater than the frequency of the second reference signal.

13. The phase locked loop circuit of claim 12, wherein the first loop comprising:
a first frequency divider for receiving the first reference signal and dividing the first reference signal to thereby generate a third reference signal;
a first phase frequency detector for generating a first phase error signal according to the third reference signal;
a charge pump for receiving the first phase error signal and generating an output control voltage;
an oscillator for generating the first output signals according to the output control voltage; and
a second frequency divider for dividing a frequency of the first output signal outputted by the phase selector to thereby generate the first feedback signal, and for passing the first feedback signal to the first phase frequency detector.

14. The phase locked loop circuit of claim 12, wherein the control loop comprising:
a second phase frequency detector for generating a second phase error signal according to the second reference signal and a second feedback output signal;
a gain control device for generating a digital control signal according to the second phase error signal;
a numerically controlled voltage oscillator for generating the phase selector signal according to the digital control signal; and
a third frequency divider for dividing the second output signal to thereby generate the second feedback output signal.

15. The phase locked loop circuit of claim 14, wherein the gain control device is a proportional-integral controller.

16. The phase locked loop circuit of claim 15, wherein the gain control device comprises:
a numerical pump for generating a ratio output signal and an accumulated output signal according to the second phase error signal; and
a digital filter for generating the digital control signal according to the ratio output signal and the accumulated output signal.

17. The phase locked loop circuit of claim 14, wherein the numerically controlled oscillator is a sigma-delta modulator.

18. The phase locked loop circuit of claim 12, wherein the second reference signal is a horizontal synchronization signal.
